(19) United States
(12) Patent Application Publication
(10) Pub. No.: US 2005/0170657 A1
(43) Pub. Date: Aug. 4, 2005

(54) Method of forming nanostructure

(75) Inventors: Yoon-ho Khang, Gyeonggi-do (KR); Byoung-Iyong Choi, Seoul (KR)

Correspondence Address: BURNS DOANE SWECKER & MATHIS L L P, POST OFFICE BOX 1404, ALEXANDRIA, VA, 22313-1404, US

(73) Assignee: Samsung Electronics Co., Ltd., Gyeonggi-do (KR)

(21) Appl. No.: 10/947,348

(22) Filed: Sep. 23, 2004

(30) Foreign Application Priority Data
Jan. 30, 2004 (KR) 10-2004-0006114

(51) Int. Cl. H01L 29/06

(52) U.S. Cl. 438/706

(57) ABSTRACT

Provided is a method of forming a nanostructure using surface plasmon resonance (SPR). The method includes forming a photo-resist layer on a substrate, forming nanostructure materials on the photo-resist layer, photo-sensitizing the photo-resist layer by irradiating light to the substrate on which nanostructure materials are formed, developing the photosensed photo-resist layer, and forming a nanostructure on the substrate by etching the substrate using the developed photo-resist layer. The method provides a high efficiency of manufacturing process and easy forming a nanostructure on a large area of substrate since the method applies SPR to nanostructure materials formed in advance on a photo-resist layer.

### BACKGROUND OF THE INVENTION

This application claims the priority of Korean Patent Application No. 2004-6114, filed on Jan. 30, 2004, in the Korean Intellectual Property Office, the disclosure of which is incorporated herein in its entirety by reference.

1. Field of the Invention

The present invention relates to a method of forming a semiconductor device, and more particularly, to a method of forming a nanostructure using a surface plasmon resonance (SPR).

2. Description of the Related Art

Methods of forming a silicon based nanostructure are being actively investigated.

A conventional method of forming a nanostructure is a method of forming an island type nanostructure by depositing a material having a large lattice mismatch onto a substrate under a proper condition. This method has an advantage of simplicity in forming a nanostructure such as a quantum dot on a substrate, but also has a drawback in that it is difficult to form a nanostructure with uniform size or high density.

As an alternative method, there is a method of forming a nanostructure by applying a physical force to a substrate by using a sharp probe. This method can form a nanostructure having a relatively uniform size and high density, but this method is inefficient for forming a nanostructure on a substrate having a wide area.

Methods for forming a nanostructure widely adopted in the current semiconductor industry are etching or depositing of a proper material after forming a desired shape on a substrate using a photolithography method or an e-beam lithography method. These methods have an advantage of controlling the nanostructure correctly and high efficiency. However, these methods have a drawback of low efficiency for manufacturing a nanostructure having a very small size such as a few nanometers.

### SUMMARY OF THE INVENTION

The present invention provides a method of forming a nanostructure using SPR (surface plasmon resource).

According to an aspect of the present invention, there is provided a method of forming a nanostructure, comprising forming a photo-resist layer on a substrate, forming nanostructure material on the photo-resist layer, photo-sensitizing the photo-resist layer by irradiating light to the substrate on which nanostructure material are formed, developing the photosensed photo-resist layer, and forming a nanostructure on the substrate by dry etching the substrate using the developed photo-resist layer.

### BRIEF DESCRIPTION OF THE DRAWINGS

The above and other features and advantages of the present invention will become more apparent by describing in detail exemplary embodiments thereof with reference to the attached drawings in which:

FIGS. 1A through 1E are cross-sectional views illustrating a method of forming a nanostructure using SPR according to an embodiment of the present invention;

FIG. 2 is a graph of light absorbed and scattered by particles versus frequency for explaining the SPR principle; and

FIG. 3 is a cross-sectional view illustrating an electromagnetic field generated directly under nanoparticles by the SPR.

### DETAILED DESCRIPTION OF THE INVENTION

The present invention will now be described more fully with reference to the accompanying drawings, in which preferred embodiments of the invention are shown. In the drawings, like reference numerals refer to like elements throughout the drawings.

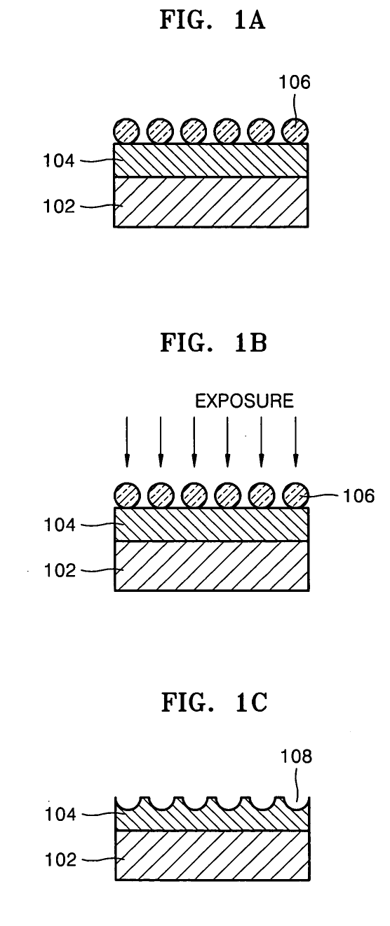

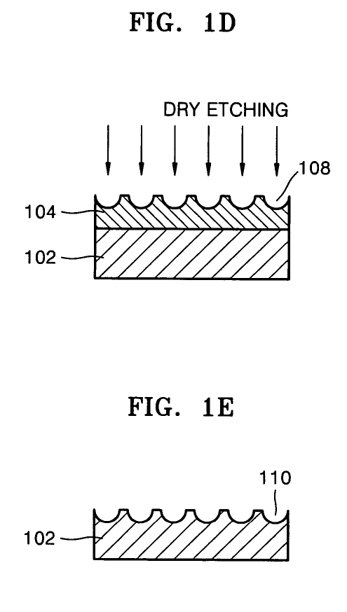

FIGS. 1A through 1E are cross-sectional views illustrating a method of forming a nanostructure using SPR according to an embodiment of the present invention.

Referring to FIG. 1A, a photo-resist layer 104 is formed on a substrate 102. Nanostructure materials 106 are formed on the photo-resist layer 104. According to an embodiment of the present invention, the photo-resist layer 104 is formed to have photo sensitivity with respect to light generated by an electromagnetic field formed by SPR of the nanostructure materials 106, in which the SPR is generated by an entered light.

The nanostructure materials 106 used for the embodiment of the present invention are nanostructures manufactured in advance using chemical and physical methods. F or example, metal nanoparticles manufactured using a chemical method can be used. The nanostructure materials 106 may be formed of a metal that can easily emit electrons and has a negative dielectric constant. The metal is selected from the group consisting of Au, Pt, Ag, Pd, Al, or Cu.

The nanostructure according to an embodiment of the present invention can be formed by a liquid phase method or a gas phase method. The liquid phase method comprises: forming a metal precursor solution from a transition metal such as Au, Ag, Pt, or Pd; injecting a metal precursor solution into a surfactant solution; adding a flocculent that precipitates nanoparticles in the solution without permanent condensation; and adding a carbon hydroxide solvent for redispersing or repeptizing of the nanoparticles.

As depicted in FIG. 1b, after coating the nanostructure materials 106 on the photo-resist layer 104, light having a predetermined wavelength and strength is irradiated to the nanostructure materials 106. At this time, the light must have a wavelength that can sensitize the photo-resist layer 104. Also, the wavelength must be a wavelength that can amplify the light generated by SPR which is generated by the nanostructure materials 106 when light is irradiated to the nanostructure materials 106. That is, by irradiating a light having a predetermined wavelength and strength, a portion of the photo-resist layer 104 close to the nanostructure materials 106 is sensitized but a portion of the photo-resist layer 104 far away from the nanostructure materials 106 remains in an unsensitized state.

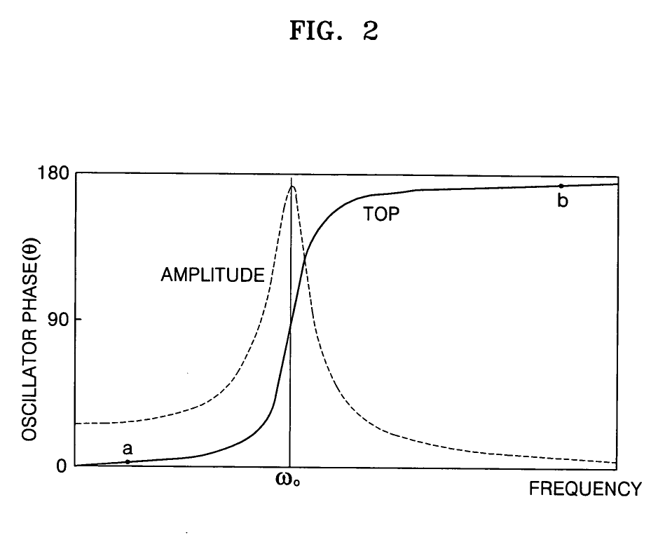

FIG. 2 is a graph of light absorbed and scattered by particles versus frequency for explaining the SPR principle.

Referring to FIG. 2, X axis represents frequency of light irradiated to the nanostructure materials 106, and Y axis represents oscillator phase of a SPR generator. Dotted lines and solid line respectively represent the amplitude and oscillator phase, and ω₀ represents the resonance frequency.

That is, when a specific wavelength of light is irradiated according to the kind of metal and size of the particles that constitute the nanostructure materials 106, a resonance effect that intensity of light increases by changing internal charge distribution of the metal particles occurs. T his phenomenon is called SPR. The light, the intensity of which is increased by the SPR, has a characteristic of reducing intensity drastically as the distance increases.

When a proper amount of light is irradiated to small metal particles, the intensity of light is increased only in the vicinity of the small metal particles. Especially, the intensity increment of light varies according to the polarized direction of the light irradiated. Using this effect, the intensity increment of light in a particular direction can be controlled. According to the embodiment of the present invention, since light intensity only in the vicinity of the nanostructure materials 106 composed of metal particles can be increased using the above phenomenon, when light with a proper wavelength and intensity is irradiated after coating metal particles on the photo-resist, the photo-resist only in the vicinity of the metal particles can be photo-sensitized.

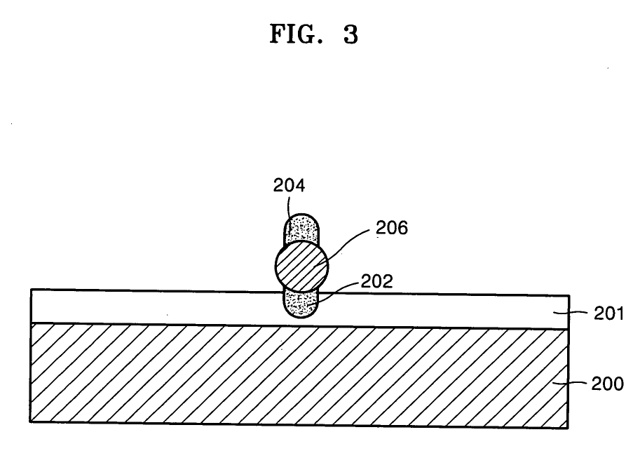

FIG. 3 is a cross-sectional view illustrating an electro-magnetic field generated directly under the nanoparticles by the SPR.

Referring to FIG. 3, a photo-resist layer 201 with a thickness of about 25 nm is formed on a glass substrate 200, and a nanostructure 206 formed on the photo-resist layer 201 is formed of silver (Ag) or gold (Au).

When the nanostructure 206 is formed of Ag, a resonance frequency is approximately 410 nm, and therefore a light irradiated to the nanostructure 206 has a frequency of 410 nm. Then, electro-magnetic fields such as 202 and 204 are formed in a vertical direction on the substrate 200 by SPR.

When the nanostructure 206 is formed of Au, a resonance frequency is approximately 537 nm, and therefore a light irradiated to the nanostructure 206 has a frequency of 537 nm. Then, electromagnetic fields such as 202 and 204 are formed in a vertical direction on the substrate 200 by SPR.

Afterward, as depicted in FIG. 1C, the nanostructure materials 106 are removed by washing or other means, and the photo-resist layer 104 is developed. Then, a photo-resist layer 104 having a sunken shape 108 on which nanostructure materials 106 have existed is obtained.

As depicted in FIG. 1D, the resultant product is etched using the photo-resist layer 104 having the sunken shape 108 as an etch pattern. In this case, the sunken portion of the photo-resist layer 104 is etched earlier than the unsunken portion of the photo-resist layer 104 since the sunken portion is thinner than the unsunken portion of the photo-resist layer 104. The semiconductor substrate 102 is also etched in the same pattern.

According to the embodiment of the present invention, a dry etching method such as a reactive ion etching (RIE) can be used for etching the resultant product. When a dry etching method is used, since the unsunken portion of the photo-resist layer 104 is thick relative to the sunken portion of the photo-resist layer 104, the photo-resist layer 104 is removed later than the sunken portion. The semiconductor substrate 102 is also etched at the same ratio.

Accordingly, as depicted in FIG. 1e, a substrate 102 having nanostructures with sunken portion 108 on which nanostructure materials 106 were existed can be manufactured.

According to the embodiment of the present invention, since SPR is applied to nanostructure materials formed in advance on photo-resist layer, this method can readily applied to an existing semiconductor manufacturing process with high process efficiency, and easy to apply to manufacture a nanostructure on a wide area of substrate in a short period of time.

The method of manufacturing a nanostructure according to the present invention has an advantage of manufacturing a nanostructure having a uniform size and high density on a substrate.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A method of forming a nanostructure, comprising:
forming a photo-resist layer on a substrate;
forming nanostructure materials on the photo-resist layer;
photo-sensitizing the photo-resist layer by irradiating light to the substrate on which the nanostructure materials are formed;
developing the photosensed photo-resist layer; and
forming a nanostructure on the substrate by etching the substrate using the developed photo-resist layer.

2. The method of claim 1, wherein the nanostructure materials are formed of a metal.

3. The method of claim 2, wherein the nanostructure materials are nanoparticles.

4. The method of claim 2, wherein the nanostructure materials are formed of a metal that emits electron easily, has a negative dielectric constant, and is selected from the group consisting of Au, Ag, Cu, Pd, and Al.

5. The method of claim 1, wherein the operation of photosensitizing the photo-resist layer is performed by surface plasmon resonance (SPR).

6. The method of claim 5, wherein a shape of the nanostructure materials is transcribed by developing the photo-resist layer, and a size and shape of the transcribed shape is controlled by controlling a size and shape of the nanostructure materials.

7. The method of claim 1, wherein the nanostructure materials are formed by a liquid phase method or a gas phase method.

8. The method of claim 1, wherein, when the nanostructure materials are formed of Ag, a wavelength of light irradiated to the nanostructure materials is about 410 nm.

9. The method of claim 1, wherein, when the nanostructure materials are formed of Au, a wavelength of light irradiated to the nanostructure materials is about 537 nm.
